(19) United States
(12) Patent Application Publication
(10) Pub. No.: US 2007/0196988 A1
(43) Pub. Date: Aug. 23, 2007

(54) Poly pre-doping anneals for improved gate profiles

(76) Inventors: Mehul D. Shroff, Austin, TX (US); Mark D. Hall, Austin, TX (US); Paul Grudowski, Austin, TX (US); Tab A. Stephens, Buda, TX (US); Phillip J. Stout, Austin, TX (US); Olubunmi O. Adetutu, Austin, TX (US)

Correspondence Address: HAMILTON & TERRILE, LLP, P.O. BOX 203518, AUSTIN, TX, 78720, US

(21) Appl. No.: 11/360,796

(22) Filed: Feb. 23, 2006

(51) Int. Cl. H01L 21/336

(52) U.S. Cl. 438/299; 438/197; 438/303

(57) ABSTRACT

A semiconductor process and apparatus uses a predetermined sequence of patterning and etching steps to etch a gate stack (32) formed over a substrate (11), thereby forming an etched gate (92, 94) having a vertical sidewall profile by implanting the gate stack (32) with a nitrogen (42) and a dopant (52) and then heating the polysilicon gate stack (32) at a selected temperature using rapid thermal annealing (62) to anneal the nitrogen and dopant so that subsequent etching of the polysilicon gate stack (32) creates an etched gate (92, 94) having more idealized vertical gate sidewall profiles.

### BACKGROUND OF THE INVENTION

1. Field of the Invention

The present invention is directed in general to the field of semiconductor devices. In one aspect, the present invention relates to controlling the profile of semiconductor features in semiconductor devices.

2. Description of the Related Art

As semiconductor device sizes are scaled down, the requirements for device design and fabrication continue to be tightened in order to fit more circuitry on smaller chips. As device sizes shrink, increasingly complex etch processes are used to define semiconductor device features, such as polysilicon gates. For example, a typical gate patterning process may use several steps after the doped polysilicon layer is formed and the photoresist (“PR”) is patterned, including a PR trim step (to shrink the size of the features being transferred), a hard mask etch step (which uses the PR as a mask), an ARC etch step (which uses the hard mask as a mask), a preliminary cleaning step (which includes some etching action), a break through etch step (to remove oxide and begin the poly etch), a main poly etch step (which can leave some poly on dielectric outside gate), a soft landing etch step, an overetch step (to remove all remaining undesired polysilicon) and a sidewall clean etch step (which etches sidewalls and potentially gouges the silicon substrate). TEOS (tetra ethyl ortho silicate) or silicon nitride may be used as a hard mask. Silicon nitride or amorphous carbon may be used as the ARC layer. Each type of processing may contribute separately to the etching of the polysilicon gate, making it difficult to control the vertical profiles of polysilicon gates. These etch and clean steps—in conjunction with doping, nitrogen implant (for PMOS gates) and implant damage—result in an irregular gate profile that, in many cases, deviates substantially from the ideal vertical sidewall. For example, the gate can have an “hourglass” shape, a “coke-bottle” shape, or can display a “foot” or notches (aka “mouse bites”) at the bottom and in some cases at the top of the gate. This is shown in FIG. 1 which illustrates examples of various device feature profiles 2-6 formed over a first layer 8 and substrate 7, including an idealized gate profile 2, an hourglass gate profile 3, a gate profile 4 having notches on the top, a gate profile 5 having foot extensions on the bottom, and a gate profile 6 having notches on the bottom. Such irregular or non-vertical sidewalls can adversely affect gate dimension control, short channel effect (SCE) control, and silicidation robustness, thereby negatively impacting circuit performance and yield.

Accordingly, a need exists for a semiconductor manufacturing process which provides better control of the sidewall profile on semiconductor device features, such as gate electrodes. In addition, there is a need for a fabrication process which forms a gate where hour-glassing, notches and/or mouse bites in the gate sidewall are reduced or eliminated. A gate electrode formation process is also needed that improves circuit performance and yield by improving gate dimension control, short channel effect (SCE) control, and silicidation robustness. There is also a need for improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a cross-sectional illustration of various polysilicon gate profiles that are caused by different gate patterning processes;

FIG. 2 is a partial cross-sectional view of a semiconductor structure formed at one stage of a process in accordance with various embodiments of the present invention, including a substrate, a gate dielectric layer and an unetched gate stack formed with a layer of undoped or intrinsic gate electrode material;

FIG. 3 illustrates processing subsequent to FIG. 2 after a first mask is formed to cover a predetermined circuit area, and the unetched gate stack over an exposed circuit area is implanted with an implant species, such as nitrogen;

FIG. 4 illustrates processing subsequent to FIG. 3 after the unetched gate stack over the exposed circuit area is implanted with a first dopant species;

FIG. 5 illustrates processing subsequent to FIG. 4 after the first mask is removed and one or more anneal processes are applied to the semiconductor structure;

FIG. 6 illustrates processing subsequent to FIG. 5 after a second mask is formed to cover a predetermined circuit area, and the unetched gate stack over the exposed circuit area is implanted with a second dopant species;

FIG. 7 illustrates processing subsequent to FIG. 6 after the second mask is removed and one or more anneal processes are applied to the semiconductor structure;

FIG. 8 illustrates processing subsequent to FIG. 7 after the unetched gate stack and gate dielectric layer are etched to form gate electrode structures having vertical sidewall profiles; and

FIG. 9 illustrates processing subsequent to FIG. 8 after source/drain regions are formed around the gate electrode structures and/or one or more sidewall spacers.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for fabricating a silicon-based device feature, such as a gate, by implanting a layer of undoped gate electrode material (such as polysilicon, single crystalline silicon, amorphous silicon, silicon germanium or the like) with an implant species (e.g., nitrogen), and then applying one or more rapid thermal anneal processes, either before or after subsequent pre-doping of the polysilicon layer. By annealing the implanted nitrogen and pre-doping implants before gate etching is performed, the subsequently etched gates have improved, more vertical profiles. The profile control provided by various embodiments of the present invention improves yield by improving critical dimension control at the bottom of the gates, provides robust silicide formation at the top of the gates, and extends existing silicide technologies to smaller dimensions. For example, when existing cobalt silicide layers are formed on polysilicon gate electrodes, the increased silicide resistance that occurs below gate widths of 40 nm is avoided by using the nitrogen anneal techniques disclosed herein to improve the gate electrode profiles. By extending the usefulness of existing cobalt silicide materials to smaller device geometries, the integration issues associated with newer silicide materials, such as NiSi encroachment, may be avoided.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid limiting or obscuring the present invention. Such descriptions and representations are used by those skilled in the art to describe and convey the substance of their work to others skilled in the art. It is also noted that, throughout this detailed description, certain elements in the figures are illustrated for simplicity and clarity and have not necessarily been drawn to scale. For example, the dimensions of some of the elements in the figures may be exaggerated relative to other elements to help improve the understanding of the embodiments of the present invention.

Turning now to FIG. 2, a partial cross-sectional view is depicted of a semiconductor structure 10, including a substrate 11, a gate dielectric layer 22 and an unetched gate stack 32 formed at least in part with a layer of undoped or intrinsic gate electrode material. Depending on the type of device being fabricated, the substrate 11 may be implemented as a bulk silicon substrate, single crystalline silicon (doped or undoped), or any semiconductor material including, for example, Si, SiC, SiGe, SiGeC, Ge, GaAs, InAs, InP as well as other Group III-IV compound semiconductors or any combination thereof, and may be formed as the bulk handling wafer. In addition, the substrate 11 may be implemented as the top silicon layer of a silicon-on-insulator (SOI) structure. Prior to forming the unetched gate stack 32, an insulator or dielectric layer 22 is formed by depositing or growing an insulator or high-k dielectric (e.g., silicon dioxide, oxynitride, metal-oxide, nitride, etc.) over the semiconductor substrate 11 using chemical vapor deposition (CVD), plasma-enhanced chemical vapor deposition (PECVD), physical vapor deposition (PVD), atomic layer deposition (ALD), thermal oxidation, or any combination(s) of the above to a thickness of approximately 5-200 Angstroms, though a thinner or thicker layer may also be used. As for the unetched gate stack 32, at least a first undoped or intrinsic polysilicon layer is formed or blanket deposited over the gate dielectric layer 22 by CVD, PECVD, PVD, ALD, or any combination(s) thereof to a thickness of approximately 500-2000 Angstroms, though a thinner or thicker layer may also be used. As will be appreciated, the unetched gate stack 32 is formed to cover the entire top surface of the silicon substrate 11, including the first and second circuit areas 12, 13, may be formed with amorphous or single crystal silicon material, and may include one or more conductive layers (e.g., metal, silicide or the like).

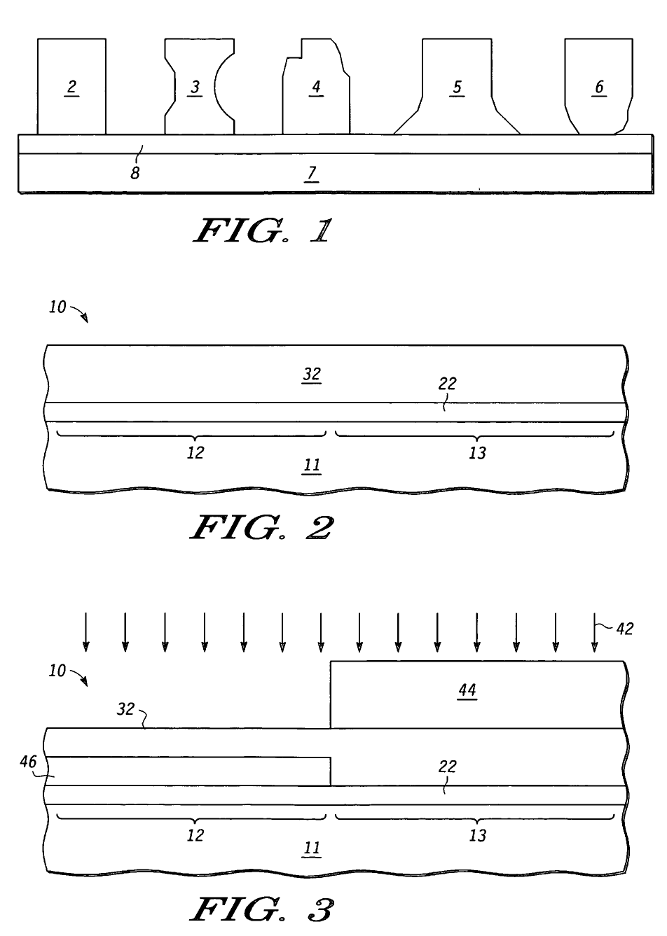

FIG. 3 illustrates processing of the semiconductor structure 10 subsequent to FIG. 2 after a first mask 44 is formed to cover a second circuit area 13. With the mask 44 in place, the unetched gate stack 32 over a first circuit area 12 is implanted with an implant species 42, such as nitrogen. Any desired patterning and etch sequence may be used to form the first mask 44 over the second circuit area 13, including but not limited to depositing, patterning and etching a photoresist or hard mask layer. Once the gate stack polysilicon layer 32 over the first circuit area 12 is cleared of resist, an implant species 42, such as nitrogen, is implanted into the exposed gate stack polysilicon layer 32. The mask may be formed over a capping layer for reducing defectivity and for better control of the implant penetration depth. One advantage of implanting nitrogen into the polysilicon layer 32 where p-type poly will subsequently be formed is that polysilicon grain boundaries are effectively stuffed by the implanted species (e.g., nitrogen), thereby preventing dopant (e.g., boron) penetration into the gate oxide and transistor channel and the resultant increase in gate leakage, degradation in gate oxide integrity, and reduction in threshold voltage. Depending on the implant conditions, the concentration profile of the implanted species 42 will create a region 46 at a predetermined depth in the gate stack polysilicon layer 32 in which the implant species concentration peaks. In a selected embodiment, the nitrogen 42 is implanted with an implant energy of approximately 10-20 keV and a dosage of approximately 5×10¹⁴ to 1×10¹⁶ cm⁻², though other implant energies and dosages may be used, depending on the thickness of the polysilicon layer. Of course, other implant materials 42 may be used as a diffusion retardation species, such as xenon, germanium, etc. As implanted, the peak nitrogen concentration depth may be located at or below the middle of the gate stack polysilicon layer 32 to help prevent boron penetration into the gate dielectric layer 22. For example, in a polysilicon layer that is 1000 Angstroms thick, the peak nitrogen concentration is located at least 500 Angstroms below the upper surface of the polysilicon layer. However, due to the distributed nature of the nitrogen implant profile, the peak nitrogen concentration region 46 may be located at any depth in the gate stack polysilicon layer 32 and still reduce boron penetration. It should be noted that the formation of the first mask 44 is an optional step, and in various embodiments of the present invention, the entirety of the gate stack polysilicon layer 32 may be implanted with the implant species without a mask being in place.

FIG. 4 illustrates processing of the semiconductor structure 10 subsequent to FIG. 3 after the unetched gate stack 32 over the first circuit area 12 is implanted with a first dopant species 52. In an example implementation where the gate stack polysilicon layer 32 over the first circuit area 12 will be used to form p-poly gate electrodes, the first dopant species 52 is boron. Depending on the implant conditions, the concentration profile of the implanted boron 52 will create a region 54 at a predetermined depth in the gate stack polysilicon layer 32 in which the boron concentration peaks. Though the specific boron implant conditions may be selected depending on the thickness of the polysilicon layer 32, a selected example dopes the polysilicon layer 32 with ¹¹B⁺ implanted at approximately 2-10 keV energy having a dose of approximately 5×10¹⁴ to 5×10¹⁶ cm⁻². As implanted, the peak boron concentration region 54 may be located above the peak nitrogen region 46 in the gate stack polysilicon layer 32 to help prevent boron penetration into the gate dielectric layer 22. In other words, the implant conditions are controlled so that the average depth of the implanted nitrogen in the polysilicon layer is below the average depth of the implanted boron. For example, in a polysilicon layer that is 1000 Angstroms thick, the peak boron concentration is located no more than 500 Angstroms below the upper surface of the polysilicon layer. Again, due to the distributed nature of the nitrogen and boron implant profiles, the peak nitrogen concentration region 46 may be located at any depth in the gate stack polysilicon layer 32 and still reduce boron penetration. In an alternative embodiment, the implantation of the first dopant species, for example, boron, may be completely eliminated. Subsequent source/drain implants could then be used to provide the needed dopant levels in the gate electrode.

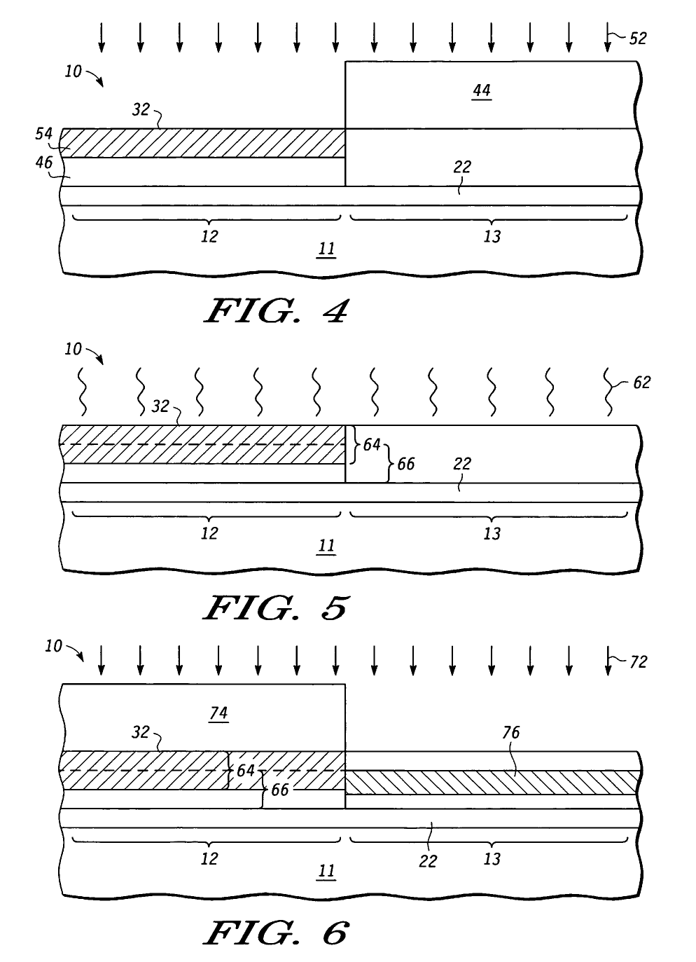

While the presence of the implanted nitrogen helps reduce or prevent boron penetration into the gate dielectric layer 22 in the finally completed device, the nitrogen can also adversely impact the sidewall profile of the subsequently etched gate electrode structures, resulting in irregular (e.g., hourglass shaped) sidewall profiles. In connection with various embodiments of the present invention, specially controlled heat anneal steps may be used to alleviate these sidewall profile effects, leading to improved critical dimension control in the finally etched gate electrode structures. An illustrative embodiment is depicted in FIG. 5, which illustrates processing of the semiconductor structure 10 subsequent to FIG. 4 after one or more rapid thermal anneal processes 62 are applied to anneal the implanted nitrogen region 66 and boron region 64 in accordance with selected embodiments of the present invention. While the regions 64, 66 are depicted in FIG. 5 as being larger than the corresponding implanted regions 54, 46 (shown in FIG. 4), the RTA process 62 need not physically disperse or drive the implanted species, but does act to change the material properties of the implanted nitrogen 66 so that the subsequently etched gate electrode structures have a substantially vertical profile with reduced hour-glassing. In a selected embodiment, a rapid thermal anneal (RTA) process 62 is applied to heat the semiconductor structure 10 to a relatively moderate temperature for a short time (e.g., approximately 700-1100° C. for between 10-60 seconds). In another embodiment, the semiconductor structure 10 is heated to a temperature between approximately 800-1000° C. for a short time (e.g., between 5-60 seconds). The RTA process 62 impacts the implanted nitrogen so that the nitrogen-based sidewall profile effects on gate profiles are reduced or eliminated. In a selected embodiment, the improved gate profiles may be obtained by annealing the nitrogen with the RTA process 62 that does not use very high temperatures (e.g., 1100-1200° C.). In addition, while the RTA anneal process 62 may be done in the presence of nitrogen gas, other gases (such as helium, argon, oxygen, etc) may also be used. Without wishing to be limited or bound by theory, the improved profiles may be caused by microchemical changes in the material composition of the gate stack polysilicon layer 32, though other mechanisms are possible. As will be appreciated, various RTA processes 62 may be used, including adding a spike anneal (e.g., 1000-1100° C. for approximately less than one second) or adjusting the parameters of the anneal based on what materials, thicknesses and implant species are used to form the gate stack polysilicon layer 32. Also, when other diffusion retardation species are used, the temperatures and other anneal conditions may be adjusted appropriately.

Such alternative implementations are described beginning with FIG. 6, which illustrates processing of the semiconductor structure 10 subsequent to FIG. 5 after a second mask 74 is formed to cover the first circuit area 12 and the unetched gate stack 32 over the second circuit area 13 is implanted with a second dopant species 72. In an example implementation where the gate stack polysilicon layer 32 over the second circuit area 13 will be used to form n-poly gate electrodes, the second dopant species 72 is phosphorus or arsenic. Depending on the implant conditions, the concentration profile of the second dopant species 72 will create a region 76 at a predetermined depth in the gate stack polysilicon layer 32 in which the concentration of the second dopant species peaks. Though the specific implant conditions may be selected depending on the thickness of the polysilicon layer 32, a selected example dopes the polysilicon layer 32 with phosphorus implanted at approximately 5-20 keV energy having a dose of approximately 5×10¹⁴ to 5×10¹⁶ cm⁻². Though the selected n-type dopants 72 do not exhibit the same migration tendencies as noted above for boron, the placement of the region 76 in relation to the implanted nitrogen region (assuming nitrogen was implanted in the second circuit area 13) will nonetheless be controlled precisely for both Npoly and Ppoly layers.

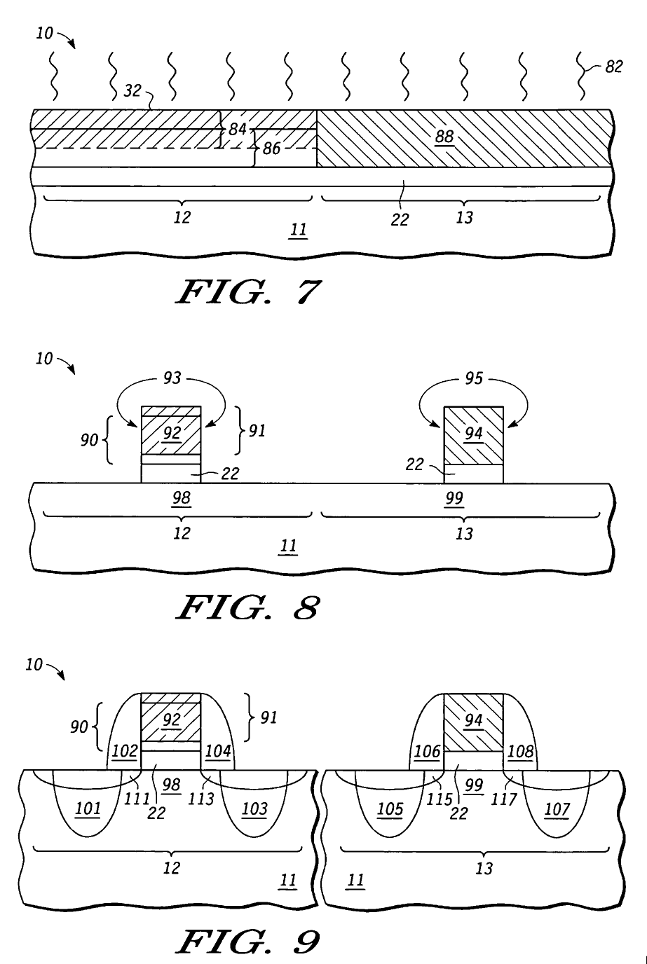

FIG. 7 illustrates processing of the semiconductor structure 10 subsequent to FIG. 6 after one or more anneal processes 82 are applied to anneal at least the second dopant species region 88 in accordance with selected alternative embodiments of the present invention. In these alternative embodiments, the nitrogen anneal process 62 (described with reference to FIG. 5) is replaced or supplemented with the anneal process(es) 82. The anneal can be rapid thermal anneal, furnace anneal, spike anneal or laser anneal. For example, a rapid thermal anneal (RTA) process 82 may be used to heat the semiconductor structure 10 to a relatively moderate temperature for a short time (e.g., approximately 700-1100° C. for between 5-60 seconds). In addition, the RTA process 82 also impacts the implanted nitrogen 86 as explained above so that the nitrogen-based sidewall profile effects on gate profiles are reduced or eliminated. Again, the RTA process 82 need not physically disperse or drive the dopant implanted species, but may instead merely change the material properties of the implanted nitrogen 86. It will be appreciated that the RTA process 82 may be used alone to anneal the previously implanted nitrogen 42, or alternatively the RTA process 82 may act in combination with an earlier RTA process 62 to anneal the implanted nitrogen 42. Additional RTA processes may be used, including adding a spike anneal (e.g., 1000-1100° C. for approximately less than one second) or adjusting the parameters of the RTA based on what materials, thicknesses and implant species are used to form the gate stack polysilicon layer 32. As will be appreciated, the anneal may be applied after the second implant, thereby providing additional flexibility for improving the NPoly profiles.

FIG. 8 illustrates processing of the semiconductor structure 10 subsequent to FIG. 7 after the unetched gate stack 32 is etched to form gate electrode structures 92, 94 in the first and second circuit areas 12, 13. Any desired gate patterning and etch sequence may be used to form the etched gate electrode structures 92, 94, including but not limited to photoresist or a hard mask formation, hard mask etch (using the photoresist as a mask), ARC etch (using the remnant hard mask as a pattern mask), an optional pre-etch cleaning, oxide break through, main poly plasma etch, soft landing etch, poly clean overetch, and post-etch cleaning. In the second circuit area 13, the etched gate electrode structure 94 defines a first channel region 99 in the substrate 11. And in the first circuit area 12, the etched gate electrode structure 92 defines a second channel region 98 in the substrate 11, and includes an upper boron-implanted region 91 and a lower nitrogen-implanted region 90 that blocks or reduces boron migration through the gate dielectric layer 22. As a result of having previously implanted and annealed the nitrogen and dopants, the selective etching of the unetched gate stack 32 forms etched gate electrode structures 92, 94 having sidewalls 93, 95 that are vertical or at least substantially vertical as compared to etched polysilicon layers that include implanted nitrogen that is not annealed.

FIG. 9 illustrates processing of the semiconductor structure 10 subsequent to FIG. 8 after source/drain regions are formed around the gate electrode structures 92, 94. While any desired source/drain structure and formation sequence may be used to form the completed transistor structures, the illustrative example forms source/drain regions by implanting halo regions (not shown) and/or shallow extension regions 111, 113, 115, 117 around the etched gate stack structures 92, 94 using conventional implanting processes to implant ions having a predetermined conductivity type. For example, when the gate electrode structures 94 are intended for N channel operation, the extension source/drain regions 115, 117 are implanted with arsenic or phosphorus, though other dopants could be used. When the gate electrode structures 92 are intended for P channel operation, the extension source/drain regions 111, 113 are implanted with boron or another appropriate dopant. During implantation of the source/drain regions 111, 113, 115, 117, each gate electrode structure 92, 94 may include a liner layer (not shown) to protect the gate electrode structures 92, 94. In addition, it will be appreciated that a masking layer (not shown) may be formed over the second circuit area 13 during implantation of the source/drain regions 111, 113 in the first circuit area 12. Likewise, a masking layer (not shown) may be formed over the first circuit area 12 during implantation of the source/drain regions 115, 117 in the second circuit area 13. The source/drain regions 111, 113, 115, 117 may be implanted very near the etched gate stack structures 92, 94 through a thin sidewall spacer or liner oxide (not shown) formed on the etched gate stack structures 92, 94 and exposed substrate 11 prior to implantation. In keeping with conventional processes, the implanted ions are annealed or heated to drive or diffuse the implanted ions into the substrate 11 to form the source and drain regions 111, 113, 115, 117.

As also illustrated in FIG. 9, additional source/drain regions 101, 103, 105, 107 may also be formed in the substrate 11 by implanting ions around sidewall spacers 102, 104, 106, 108 formed on the gate electrode structures 92, 94. The sidewall spacers 102, 104, 106, 108 may be formed by depositing one or more relatively thick dielectric layers (e.g., a 500 Angstrom layer of nitride) over the semiconductor structure 10 using any desired deposition process, and then anisotropically etching the deposited dielectric layer to form the sidewall spacers 102, 104, 106, 108. Depending on the constituent materials and dimensions of the deposited dielectric layer(s), the etching may use one or more anisotropic etch processes to form sidewall spacers 102, 104, 106, 108, including a dry etching process (such as reactive-ion etching, ion beam etching, plasma etching or any combination thereof. In a selected illustrative embodiment, the sidewall spacer processing details may be selected to obtain on each side a minimum predetermined total spacer width (e.g., approximately 200-700 Angstroms). Once the sidewall spacers 102, 104, 106, 108 are in place, additional source/drain regions 101, 103, 105, 107 may be formed by implanting the predetermined ions around the etched gate stack structures 92, 94 and sidewall spacers 102, 104, 106, 108, again using conventional implanting processes. For example, the source/drain regions 101, 103, 105, 107 may be formed as deep source/drain regions using the appropriate dopant for the intended type of device (e.g., NMOS or PMOS). In keeping with conventional processes, the implanted ions are annealed or heated to activate, drive or diffuse the implanted ions into the substrate 11 to form the source/drain regions 101, 103, 105, 107.

It will be appreciated that additional processing steps will be used to complete the fabrication of the gate electrodes into functioning transistors or devices. As examples, one or more sacrificial oxide formation, stripping, isolation region formation, extension implant, halo implant, spacer formation, source/drain implant, heat drive or anneal steps, and polishing steps may be performed, along with conventional backend processing (not depicted) typically including formation of multiple levels of interconnect that are used to connect the transistors in a desired manner to achieve the desired functionality. Thus, the specific sequence of steps used to complete the fabrication of the gate electrodes may vary, depending on the process and/or design requirements.

In one form, there is provided herein a method for fabricating a semiconductor device by forming a gate dielectric layer and an undoped gate electrode layer over a semiconductor substrate, where the gate electrode layer may include an intrinsic or undoped polysilicon layer. Next, a first implant species (such as nitrogen, xenon, germanium or a dopant, such as boron) is implanted into the gate electrode layer in a first circuit area. At this point, a first dopant species may also be implanted into the first circuit area, in which case the first implant species may be implanted to an average depth in the gate electrode layer that is below an average depth of the implanted first dopant species. Subsequently, the gate electrode layer is heated at a selected temperature, such as by using rapid thermal annealing, to anneal the first implant species so that subsequent selective etching of the gate electrode layer creates etched gates that have substantially vertical sidewalls with substantially no hour-glassing. In a selected embodiment, the gate electrode layer is heated in the presence of a gas (e.g., nitrogen, helium, oxygen or argon) using rapid thermal annealing to a temperature between approximately 700-1100° C. for between 5-60 seconds, though the RTA may be supplemented or replaced with a spike anneal process. In various CMOS-type processes, a second dopant species may be implanted into the gate electrode layer in a second circuit area before or after the gate electrode layer is first heated with the initial RTA. If the second dopant species is implanted before any RTA process, then all of the implanted species may be annealed in a single step. Alternatively, if the second dopant species is implanted after the initial RTA process, then an additional heating step may be applied to anneal all of the implanted species with the additional heating step, taking into account the prior annealing of the first implant species and first dopant species during the initial RTA process.

In another form, there is provided a method for forming a gate electrode by depositing an intrinsic polysilicon layer over a gate dielectric layer formed over a substrate. In a first circuit area of the polysilicon layer, a first species and first dopant species are implanted, and then a second dopant species may be implanted in a second circuit area of the polysilicon layer. By annealing the polysilicon layer, the first species, first dopant species and second dopant species are heated at a selected temperature to change the material properties of at least the implanted first species. In a selected embodiment, the polysilicon layer is annealed in the presence of an inert gas (e.g., nitrogen, helium or argon) using a spike anneal or rapid thermal anneal process at a temperature between approximately 800-1000° C. for between 5-60 seconds. As a result, subsequent etching of the polysilicon layer creates an etched gate electrode having substantially vertical sidewalls.

In yet another form, a method of fabricating a polysilicon device feature is disclosed whereby a first part of an undoped polysilicon layer is implanted with a diffusion retardation species and a dopant species before applying a rapid thermal anneal process to anneal at least the implanted diffusion retardation species. In addition, a second part of the undoped polysilicon layer may be implanted with a second dopant species, either before or after the rapid thermal anneal process. Finally, the polysilicon layer is etched to form a polysilicon device feature having substantially vertical sidewalls.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the depicted transistor structures may also be formed in a well region (not shown) of the substrate which may be an n-doped well or a p-doped well. Also, the various silicon-based constituent layers may be formed with different conductive materials than those disclosed. In addition, the source and drains and extensions may be p-type or n-type, depending on the polarity of the underlying substrate or well region, in order to form either p-type or n-type semiconductor devices. Moreover, the thickness of the described layers may deviate from the disclosed thickness values. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. In selected embodiments, the disclosed semiconductor manufacturing processes improve gate profiles to reduce or eliminate the process and performance limitations associated with non-vertical gate sidewalls. For example, critical gate dimension control and/or short channel effect (SCE) control may be maintained or improved by reducing or eliminating hour-glassing. Another advantage that may occur in selected embodiments is that more robust silicide can be fabricated by forming gates having vertical sidewall profiles. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for forming a semiconductor device comprising:
providing a semiconductor substrate;
forming a gate dielectric layer over the semiconductor substrate;
forming an undoped gate electrode layer over the gate dielectric layer;
implanting a first implant species into the gate electrode layer in a first circuit area;
heating the gate electrode layer at a selected temperature using rapid thermal annealing to anneal the first implant species so that subsequent etching of the gate electrode layer creates an etched gate having substantially vertical sidewalls; and
selectively etching the gate electrode layer to form an etched gate having substantially vertical sidewalls.

2. The method of claim 1, comprising implanting a first dopant species into the gate electrode layer in the first circuit area prior to selectively etching the gate electrode layer.

3. The method of claim 2, where implanting the gate electrode layer with a first implant species comprises implanting nitrogen to an average depth in the gate electrode layer that is below an average depth of the implanted first dopant species.

4. The method of claim 2, further comprising implanting a second dopant species into the gate electrode layer in a second circuit area before heating the gate electrode layer.

5. The method of claim 1, where heating the gate electrode layer comprises heating the gate electrode layer at a temperature between approximately 700-1100° C. for between 5-60 seconds.

6. The method of claim 1, where heating the gate electrode layer comprises heating the gate electrode layer at a temperature between approximately 800-1000° C.

7. The method of claim 1, where heating the gate electrode layer comprises heating the gate electrode layer in the presence of a gas selected from the group consisting of nitrogen, helium, oxygen and argon.

8. The method of claim 1, where the first implant species comprises nitrogen, xenon or germanium.

9. The method of claim 1, further comprising heating the gate electrode layer with a spike anneal after using rapid thermal annealing.

10. The method of claim 1, where heating the gate electrode layer comprises a spike anneal process.

11. The method of claim 1, where the undoped gate electrode layer comprises a layer of intrinsic polysilicon.

12. The method of claim 1, where the substantially vertical sidewalls have substantially no hour-glassing.

13. A method for forming a gate electrode, comprising:
depositing an intrinsic polysilicon layer over a gate dielectric layer formed over a substrate;
implanting a first species into the polysilicon layer in a first circuit area;
implanting a first dopant species into the polysilicon layer in the first circuit area;
implanting a second species into the polysilicon layer in a second circuit area; then
annealing the polysilicon layer, first species, first dopant species and second dopant species at a selected temperature so that subsequent etching of the polysilicon layer creates an etched gate electrode having substantially vertical sidewalls; and
selectively etching the polysilicon layer to form an etched gate electrode having substantially vertical sidewalls.

14. The method of claim 13, where annealing the polysilicon layer comprises heating the polysilicon layer at a temperature between approximately 800-1000° C. for between 5-60 seconds.

15. The method of claim 13, where heating the polysilicon layer comprises heating the polysilicon layer in the presence of an inert gas selected from the group consisting of nitrogen, helium and argon.

16. The method of claim 13, where annealing the polysilicon layer comprises a rapid thermal anneal or spike anneal process.

17. The method of claim 13, where implanting a first species comprises implanting nitrogen to an average depth in the polysilicon layer that is below an average depth of the first dopant species.

18. A method of fabricating a polysilicon device feature comprising:
implanting at least part of an undoped polysilicon layer with a diffusion retardation species and a dopant species;
applying one or more rapid thermal anneal processes to anneal the implanted diffusion retardation species; and then
etching the polysilicon layer to form a polysilicon device feature having substantially vertical sidewalls.

19. The method of claim 18, further comprising implanting a second part of the undoped polysilicon layer with a second dopant species prior to applying one or more rapid thermal anneal processes.

20. The method of claim 18, further comprising implanting a second part of the undoped polysilicon layer with a second dopant species after applying one or more rapid thermal anneal processes.
